(19) United States
(12) Patent Application Publication
(10) Pub. No.: US 2026/0190936 A1
(43) Pub. Date: Jul. 2, 2026

(54) STOCKER AND ARTICLE TRANSFER SYSTEM

(71) Applicant: SEMES CO., LTD., Cheonan-si, (KR)

(72) Inventor: Jin Ho SONG, Seongnam-si (KR)

(21) Appl. No.: 19/406,863

(22) Filed: Dec. 2, 2025

(30) Foreign Application Priority Data
Dec. 30, 2024 (KR) 10-2024-0199977

(51) Int. Cl. H10P 72/30; B65G 1/137; B66C 19/00

(52) U.S. Cl. CPC H10P 72/3404; B65G 1/1371; B66C 19/00; H10P 72/3214; H10P 72/3221; H10P 72/3402; B65G 2201/0297

(57) ABSTRACT

A stocker including a main frame, and a plurality of storage units disposed in a vertical direction and a horizontal direction in the main frame. Each of the plurality of storage units includes a sliding shelf that is withdrawable in both forward and backward directions in a depth direction of the main frame. The sliding shelf directly loads an article from an overhead hoist transport (OHT) vehicle or directly unloads the article from the sliding shelf to the OHT vehicle.

### CROSS-REFERENCE TO RELATED APPLICATION(S)

This application claims benefit of priority to Korean Patent Application No. 10-2024-0199977 filed on Dec. 30, 2024 in the Korean Intellectual Property Office, the disclosure of which is incorporated herein by reference in its entirety.

### BACKGROUND

### 1. Field

The present disclosure relates to a stocker and an article transfer system.

### 2. Description of Related Art

An overhead hoist transport (OHT) system may transfer articles required for processes while moving along an article transfer path on a ceiling side of a semiconductor manufacturing factory.

A stocker may be installed on a lateral side of the article transfer path to store articles, such as wafers, transferred by an OHT.

Specifically, the stocker may include a plurality of shelves for storing containers for accommodating wafers, for example, front opening unified pods (FOUPs) or front opening shipping boxes (FOSBs).

In addition, the stocker may include an input/output port for an OHT vehicle, travelling along a rail laid on or in the vicinity of the ceiling, to place articles, and a crane for transferring articles between the input/output port and the plurality of shelves.

A stocker according to the related art may require an input/output port occupying a certain amount of space. Due to limitations of shelves installed in a recessed manner, space utilization efficiency may be lowered.

### SUMMARY

An aspect of the present disclosure is to provide a stocker and an article transfer system that may additionally secure storage space and increase efficiency of article loading and unloading operations.

Another aspect of the present disclosure is to provide a stocker and an article transfer system that may include a sliding shelf that is withdrawable in both directions, and thus may directly interface with an OHT vehicle without a transfer port.

Another aspect of the present disclosure is to provide a stocker and an article transfer system that may include a plurality of main frames disposed in multiple stages and may enable article loading and unloading in both forward and backward directions of the main frame, and thus may improve utilization of an operation space.

The aspects of the present disclosure are not limited to those set forth herein. A person having ordinary skill in the art to which the present disclosure pertains may have no difficulty in understanding additional aspects of the present disclosure from the overall contents of the present specification.

According to an aspect of the present disclosure, there is provided a stocker including a main frame, and a plurality of storage units disposed in a vertical direction and a horizontal direction in the main frame. Each of the plurality of storage units may include a sliding shelf that is withdrawable in both forward and backward directions in a depth direction of the main frame. The sliding shelf may directly load an article from an overhead hoist transport (OHT) vehicle or directly unload the article from the sliding shelf to the OHT vehicle.

According to another aspect of the present disclosure, there is provided an article transfer system including a traveling rail installed on a ceiling of a facility, a vehicle moving along the traveling rail and transferring an article, and a stocker exchanging the article with the vehicle, the stocker including a plurality of storage units storing the article. The plurality of storage units may be disposed in a vertical direction and a horizontal direction in a main frame of the stocker. Each of the plurality of storage units may include a sliding shelf that is withdrawable in both forward and backward directions in a depth direction of the main frame. The vehicle may directly load an article onto the withdrawn sliding shelf or directly unload the article from the withdrawn sliding shelf.

According to another aspect of the present disclosure, there is provided an article transfer system including a traveling rail installed on a ceiling of a facility, a vehicle moving along the traveling rail and transferring an article, and a stocker exchanging the article with the vehicle, the stocker including a plurality of storage units storing the article. The stocker may include a plurality of main frames disposed to be spaced apart from each other in a depth direction, and a plurality of storage units disposed in a vertical direction and a horizontal direction in the plurality of main frames. Each of the plurality of storage units may include a sliding shelf that is withdrawable in both forward and backward directions in the depth direction. The vehicle may be approachable to one of the plurality of main frames through the traveling rail, and may directly load an article onto the withdrawn sliding shelf or directly unload the article from the withdrawn sliding shelf.

According to example embodiments of the present disclosure, a stocker and an article transfer system may additionally secure storage space and increase efficiency of article loading and unloading operations.

According to example embodiments of the present disclosure, a stocker and an article transfer system may include a sliding shelf that is withdrawable in both directions, thereby directly interfacing with an OHT vehicle without a transfer port.

According to example embodiments of the present disclosure, a stocker and an article transfer system may include a plurality of main frames disposed in multiple stages and may enable article loading and unloading in both forward and backward directions of the main frame, thereby improving utilization of an operation space.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a schematic view of an article transfer system according to an example embodiment of the present disclosure;

FIG. 1B is a front view of an article transfer system according to the related art;

FIG. 2 is a front view of an article transfer system according to an example embodiment of the present disclosure;

FIG. 3 schematically illustrates an operation of storing an article in a stocker of an article transfer system according to an example embodiment of the present disclosure;

FIG. 4 is a front view of an article transfer system according to another example embodiment of the present disclosure;

FIG. 5 schematically illustrates an operation of storing an article in a stocker of an article transfer system according to another example embodiment of the present disclosure; and

FIG. 6 is a schematic top view of an article transfer system according to another example embodiment of the present disclosure.

### DETAILED DESCRIPTION

Hereinafter, preferred example embodiments are described in detail with reference to the accompanying drawings such that those skilled in the art can readily practice the present disclosure. However, the example embodiments of the present disclosure may be modified into various other forms, and the scope of the present disclosure is not limited to the example embodiments described below.

In addition, example embodiments of the present disclosure are provided to further describe the present disclosure to those skilled in the art.

In the drawings, shapes, sizes, and the like of elements may be exaggerated or reduced for clearer illustration.

In describing the example embodiments of the present disclosure, when it is determined that a detailed description of a known technology related to the present disclosure may unnecessarily obscure the gist of the present disclosure, the detailed description thereof will be omitted. In addition, terms to be described below are terms defined in consideration of functions in the present disclosure, which may vary depending on intention or custom of a user or operator. Therefore, the definition of these terms should be made based on the contents throughout the present specification. The terminology used herein is for the purpose of describing particular example embodiments only and is not to be limiting of the example embodiments. As used herein, the singular forms “a,” “an,” and “the” are intended to include the plural forms as well, unless the context clearly indicates otherwise.

In addition, in the present specification, terms such as “upper,” “upper portion,” “upper surface,” “lower,” “lower portion,” “lower surface,” and “side surface” are based on the drawings, may vary depending on a direction in which an element or component is actually disposed.

When it is mentioned that one component is “connected” or “accessed” to another component, it may be understood that the one component is directly connected or accessed to another component or that still other component is interposed between the two components. In addition, it should be noted that if it is described in the specification that one component is “directly connected” or “directly joined” to another component, still other component may not be present therebetween. In addition, it will be understood that “comprises” and/or “comprising” specify the presence of stated features, integers, steps, operations, elements, components or a combination thereof, but do not preclude the presence or addition of one or more other features, integers, steps, operations, elements, components, and/or groups thereof.

Hereinafter, the present disclosure will be described in detail through each example embodiment or example. It should be noted that each example embodiment or example described herein is not limited to a single example embodiment or example, and combinations with other example embodiments or examples are also possible. Accordingly, citation of claims in the claims section correspond to only one example of an example embodiment, and the technical concept of the present disclosure should not be construed as being limited to combinations with the cited claims. Combinations with various claims are also within the scope of the technical concept of the present disclosure.

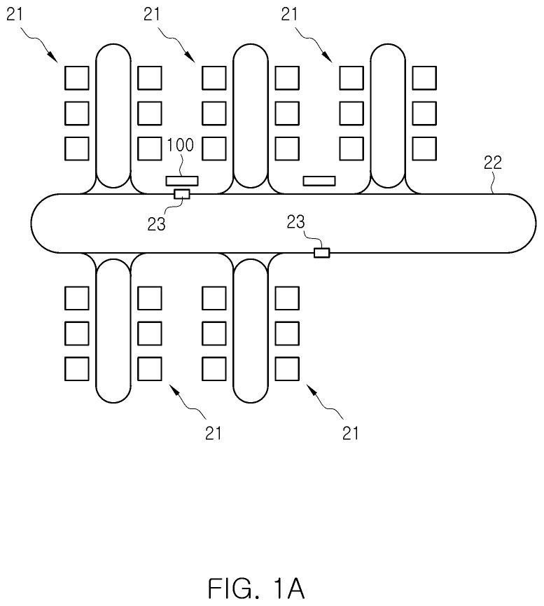

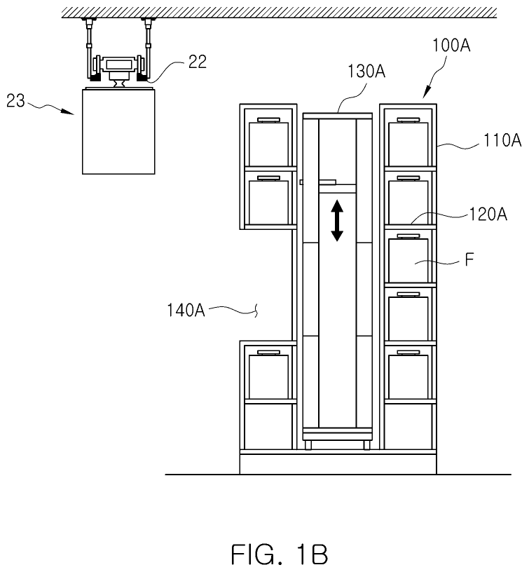

FIG. 1A schematically illustrates an article transfer system according to an example embodiment of the present disclosure. The article transfer system 1 may transfer an article between a plurality of process facilities 21. The article may include a container accommodating a substrate. The container may be, for example, a front opening unified pod (FOUP).

The article transfer system 1 may include an overhead hoist transport (OHT) facility. The article transfer system 1 may include a traveling rail 22 and a vehicle 23 to transfer the article.

The traveling rail 22 may provide a movement path for transferring the article between the plurality of process facilities 21. The traveling rail 22 may be provided to be adjacent to a ceiling of a semiconductor manufacturing facility.

The vehicle 23 may carry the article while traveling along the traveling rail 22. The vehicle 23 may transfer the article from one of the plurality of process facilities 21 to another one.

The article transfer system 1 may further include a stocker 100, a facility in which the article is stored. The vehicle 23 may transfer the article from one of the plurality of process facilities 21 to the stocker 100, or from the stocker 100 to one of the plurality of process facilities 21.

FIG. 1B illustrates a front view of an article transfer system according to the related art. Referring to FIG. 1B, a stocker 100A according to the related art may include a main frame 110A, a storage unit 120A storing an article, a transfer port 130A, and an article transfer crane 140A.

The stocker 100A according to the related art may receive an article F from a vehicle 23 through the transfer port 130A, or may provide the article F to the vehicle 23 through the transfer port 130A.

The storage unit 120A may provide a storage space for storing the article F to the inside of a fixed housing.

Transfer of the article between the transfer port 130A and the storage unit 120A may be performed using the article transfer crane 140A.

For example, the article F may be sequentially transferred from the vehicle 23 to the transfer port 130A and the article transfer crane 140A, and then to the storage units 120A.

For another example, the article F may be sequentially transferred from the storage unit 120A through the article transfer crane 140A and the transfer port 130A to the vehicle 23.

A region in which the vehicle 23 and the stocker 100A are capable of interfacing is limited to the transfer port 140A, such that the stocker 100A according to the related art may have reduced storage utilization and reduced transfer efficiency.

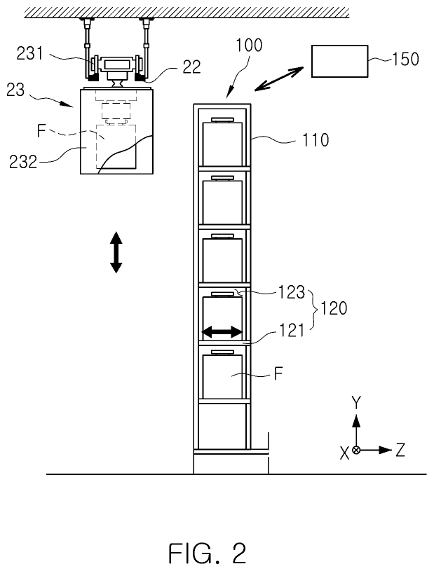

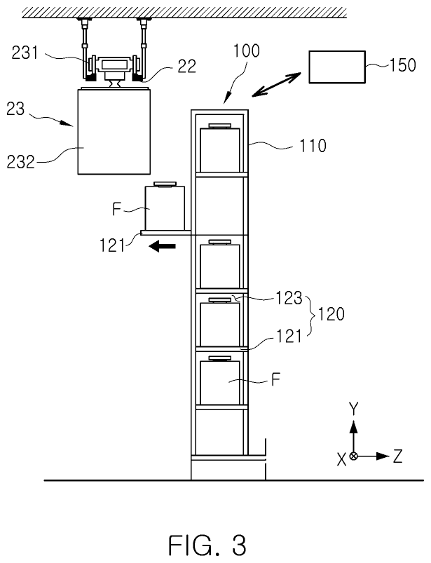

FIGS. 2 and 3 illustrate front views of an article transfer system 1 according to an example embodiment of the present disclosure. The article transfer system 1 may include a traveling rail 22, a vehicle 23, and a stocker 100.

The traveling rail 22 may be installed on a ceiling of a semiconductor facility to provide a movement path of the vehicle 23.

The vehicle 23 may carry an article F while traveling along the traveling rail 22. The article F may an FOUP in which a plurality of substrates are accommodated.

The vehicle 23 may transfer an article to the stocker 100 or receive the article from the stocker 100.

The vehicle 23 may include a vehicle traveling unit 231 and a hoist unit 232.

The vehicle traveling unit 231 may include a plurality of wheels that are movable along a guide of the traveling rail 22 and a motor for driving the plurality of wheels.

The hoist unit 232 may include a hoist housing providing a space for accommodating the article F, and a hand for gripping or ungripping the article F.

The hoist unit 232 may move the hand in a vertical direction or a horizontal direction. FIG. 2 illustrates a state in which the article F gripped by the hand of the hoist unit 232 is accommodated in the hoist housing.

The stocker 100 may be a facility exchanging the article F with the vehicle 23 and storing the article F. The stocker 100 may be installed on the floor or ceiling of the semiconductor facility, for example. The stocker 100 may be installed in a region in which the vehicle 23 is approachable through the traveling rail 22.

The stocker 100 may include a main frame 110, a plurality of storage units 120, and a control unit 150.

The main frame 110 may be fixedly installed on the floor or ceiling of the semiconductor facility. The stocker 100 may include one or more main frames 110.

In FIG. 2, a horizontal direction of the main frame 110 may be an X-axis direction, a vertical direction of the main frame 110 may be a Y-axis direction, and a depth direction of the main frame 110 may be a Z-axis direction.

The plurality of storage units 120 may be disposed in the vertical direction and the horizontal direction in the main frame 110. The plurality of storage units 120 may be disposed in a plurality of rows in the horizontal direction of the main frame 110, and may be disposed in a plurality of columns in the vertical direction of the main frame 110.

Each of the plurality of storage units 120 may include a sliding shelf 121 and a storage space 123.

The sliding shelf 121 may support the article F. The sliding shelf 121 may be installed to be withdrawable in both forward and backward directions in the depth direction of the main frame 110.

The sliding shelf 121 may directly load the article F from the vehicle 23 in a state in which the sliding shelf 121 is withdrawn in one direction. In addition, the article F may be directly unloaded from the sliding shelf 121 to the vehicle 23 in a state in which the sliding shelf 121 is withdrawn in one direction.

The storage space 123 may accommodate the article F supported by the sliding shelf 121 in a state in which the sliding shelf 121 is inserted.

The control unit 150 may manage a status of the article F stored in the plurality of storage units 120. For example, the control unit 150 may periodically update information on the storage unit 120 and information on an empty storage unit 120.

The control unit 150 may receive operation information from the vehicle 23. The operation information may include, for example, operation information on loading and unloading of the article F.

The control unit 150 may determine, based on the operation information of the vehicle 23, a target storage unit for performing article loading and unloading, among the plurality of storage units 120.

For example, when the operation information of the vehicle 23 includes a request to store the article F carried by the vehicle 23 in the stocker 100, the control unit 150 may determine an empty storage unit 120, among the plurality of storage units 120, as the target storage unit.

For another example, when the operation information of the vehicle 23 includes a request for releasing the article F stored in the stocker 100, the control unit 150 may determine the storage unit 120 storing the article F, among the plurality of storage units 120, as the target storage unit.

The control unit 150 may transmit coordinate information of the target storage unit to the vehicle 23. The vehicle 23 may move toward an upper portion of the target storage unit, based on the coordinate information of the target storage unit.

The vehicle 23 may withdraw a sliding shelf of the target storage unit, using the hand of the hoist unit 232. The sliding shelf may be withdrawable in both forward and backward directions in the depth direction of the main frame 110.

FIG. 3 illustrates a state in which the sliding shelf of the target storage unit is withdrawn by the hand of the hoist unit 232.

The vehicle 23 may load the article F onto the withdrawn sliding shelf of the target storage unit, or unload the article F from the withdrawn sliding shelf of the target storage unit.

The article transfer system according to the present disclosure may include a stocker including a sliding shelf that is withdrawable in both directions, thereby securing an additional storage space in a space occupied by a transfer port.

In addition, according to the present disclosure, a region in which a vehicle and the stocker may interface is expanded throughout the stocker, thereby increasing efficiency of article loading and unloading operations. As a result, a facility may have improved throughput.

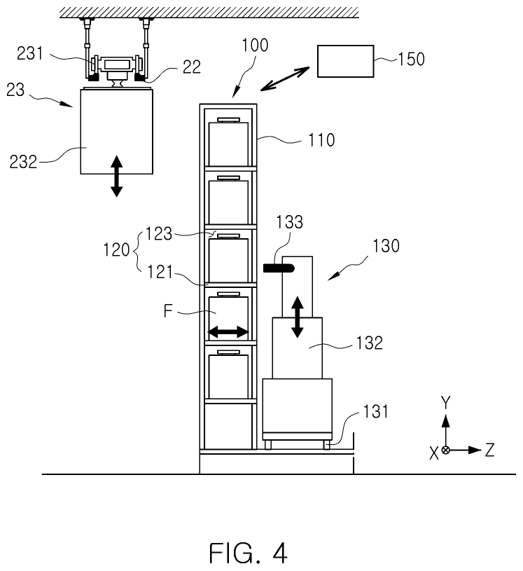

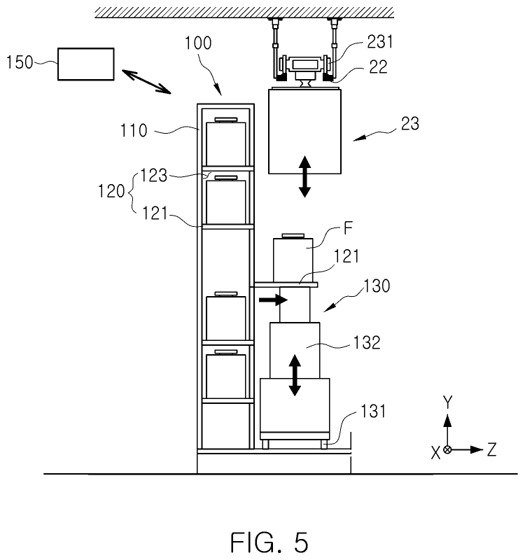

FIGS. 4 and 5 illustrate front views of an article transfer system according to another example embodiment of the present disclosure.

A stocker 100 of the article transfer system according to another example embodiment of the present disclosure may further include a slide driving unit 130. The remaining components, the same as those of the example embodiment described with reference to FIGS. 1A, 2 and 3, will be omitted.

A slide driving unit 130 may be installed to be adjacent to a main frame 110. The slide driving unit 130 may drive sliding shelves 121 of a plurality of storage units 120.

The slide driving unit 130 may withdraw the sliding shelf 121 from the main frame 110 or insert the sliding shelf 121 into the main frame 110.

The slide driving unit 130 may include a telescopic crane having a height varying in a vertical direction of the main frame 110. A height of the slide driving unit 130 may vary based on coordinate information of a target storage unit.

The slide driving unit 130 may include a traveling mechanism 131, a height adjustment mechanism 132, and a slide operation mechanism 133.

The traveling mechanism 131 may be disposed in front of or behind the main frame 110. The traveling mechanism 131 may be configured to be movable in a horizontal direction of the main frame 110. The traveling mechanism 131 may include, for example, one or more wheels.

The height adjustment mechanism 132 may be installed on an upper portion of the traveling mechanism 131. A length of the height adjustment mechanism 132 may vary, and thus may adjust an operation height of the slide driving unit 130 in the vertical direction of the main frame 110.

The slide operation mechanism 133 may withdraw the sliding shelf 121 or insert the sliding shelf 121 at the operation height.

The slide operation mechanism 133 may include, for example, a hand extending from an upper portion of the height adjustment mechanism 132.

The control unit 150 may transmit coordinate information of the target storage unit to the slide driving unit 130.

The slide driving unit 130 may move the shelf operation mechanism 133 to a vicinity of a sliding shelf of the target storage unit, using the traveling mechanism 1 131 and the height adjustment mechanism 132.

The slide driving unit 130 may withdraw the sliding shelf of the target storage unit, using the shelf operation mechanism 133.

FIG. 5 illustrates a state in which the sliding shelf of the target storage unit is withdrawn by the slide driving unit 130.

The vehicle 23 may load the article F onto the withdrawn sliding shelf of the target storage unit, or may unload the article F from the withdrawn sliding shelf of the target storage unit.

A standby state of the slide driving unit 130 may be maintained until an operation of the vehicle 23 on the sliding shelf of the target storage unit is terminated.

The slide driving unit 130 may insert the sliding shelf of the target storage unit after an article loading or unloading operation of the vehicle 23 on the sliding shelf of the target storage unit is completed.

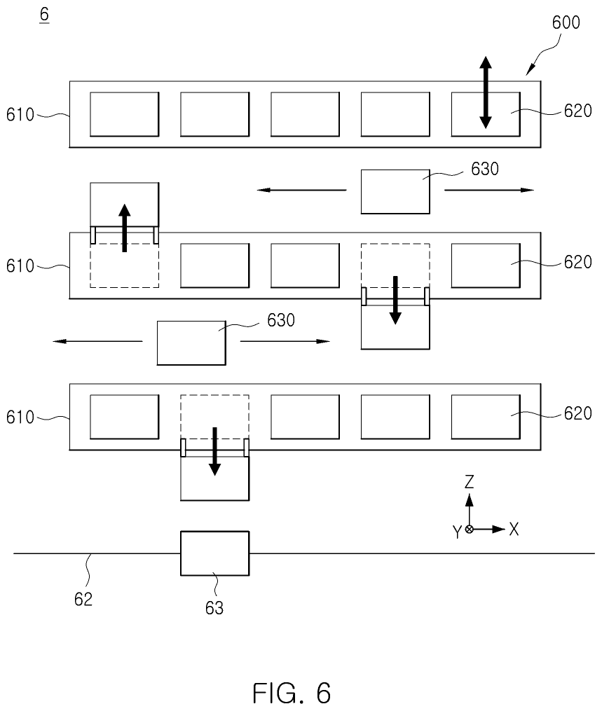

FIG. 6 is a schematic top view of an article transfer system according to another example embodiment of the present disclosure.

As illustrated in FIG. 6, an article transfer system 6 may include a traveling rail 62, a vehicle 63, and a stocker 600.

The stocker 600 may include a plurality of main frames 610, a plurality of storage units 620, and a plurality of slide driving units 630. The plurality of main frames 610 may be disposed to be spaced apart from each other in a depth direction.

In FIG. 6, a horizontal direction of the plurality of main frames 610 may be an X-axis direction, a vertical direction of the plurality of main frames 610 may be a Y-axis direction, and a depth direction of the plurality of main frames 610 may be a Z-axis direction.

The slide driving unit 630 may be installed between the plurality of main frames 610. The slide driving unit 630 may withdraw or insert a sliding shelf of the storage unit 620 in the main frame 610 at the front or back.

According to the present disclosure, a stocker and an article transfer system may include a plurality of main frames disposed in multiple stages and may enable article loading and unloading in both forward and backward directions of the main frame, thereby improving utilization of an operation space.

In some example embodiments provided in the present application, it should be understood that the device and method described herein may be implemented in other manners. For example, the above-described device example embodiment is merely an example. For example, division of the units is merely a division of logical functions, and may be other division in actual implementation. For example, a plurality of units or components may be combined or integrated into another system, or some components may be ignored or may not be performed. In addition, mutual couplings, direct couplings, or communication connections displayed or discussed may be indirect couplings or communication connections implemented using some interfaces, devices or units, and may be implemented in electrical, mechanical, or other form.

The units described above as separate parts may be physically separated from each other, and parts displayed as units may be or may not be physical units. Thus, the parts may be disposed in one position, or may be distributed on a plurality of network units. Some or all of the units may be selected based on actual requirements to achieve aspects of the present disclosure.

That is, functional units in the example embodiments of the present disclosure may be integrated into one processing unit, or each of the units may be present solely, or two or more units are integrated into one unit.

While example embodiments have been illustrated and described above, it will be apparent to those skilled in the art that modifications and variations could be made without departing from the scope of the present disclosure as defined by the appended claims. Therefore, the scope of the present disclosure should not be limited to the described example embodiments, and should be defined not only by the following claims but also by equivalents thereof.

What is claimed is:

1. A stocker comprising:
a main frame; and
a plurality of storage units disposed in a vertical direction and a horizontal direction in the main frame,
wherein each of the plurality of storage units includes a sliding shelf that is withdrawable in both forward and backward directions in a depth direction of the main frame, and
the sliding shelf directly loads an article from an overhead hoist transport (OHT) vehicle or directly unloads the article from the sliding shelf to the OHT vehicle.

2. The stocker of claim 1, further comprising:
a control unit managing a status of an article stored in the plurality of storage units.

3. The stocker of claim 2, wherein the control unit receives operation information from the OHT vehicle, determines, based on the operation information, a target storage unit for performing article loading and unloading, among the plurality of storage units, and transmits coordinate information of the target storage unit to the OHT vehicle.

4. The stocker of claim 3, wherein a sliding shelf of the target storage unit is withdrawn by a hoist hand of the OHT vehicle, and an article is loaded from the OHT vehicle onto the sliding shelf of the target storage unit or unloaded from the sliding shelf of the target storage unit to the OHT vehicle.

5. The stocker of claim 3, further comprising:
a slide driving unit installed to be adjacent to the main frame, the slide driving unit driving the sliding shelf.

6. The stocker of claim 5, wherein the slide driving unit includes a telescopic crane having a height varying in a vertical direction of the main frame, based on the coordinate information of the target storage unit.

7. The stocker of claim 5, wherein the slide driving unit includes:
a traveling mechanism disposed in front of or behind the main frame, the traveling mechanism movable in a horizontal direction of the main frame;
a height adjustment mechanism installed on an upper portion of the traveling mechanism, the height adjustment mechanism adjusting an operation height in a vertical direction of the main frame; and
a shelf operation mechanism withdrawing or inserting the sliding shelf at the operation height.

8. The stocker of claim 7, wherein
the control unit transmits the coordinate information of the target storage unit to the slide driving unit, and
the slide driving unit moves the shelf operation mechanism to a vicinity of a sliding shelf of the target storage unit, using the traveling mechanism and the height adjustment mechanism.

9. The stocker of claim 8, wherein the slide driving unit withdraws the sliding shelf of the target storage unit, using the shelf operation mechanism.

10. The stocker of claim 9, wherein the slide driving unit inserts the sliding shelf of the target storage unit after an article loading or unloading operation of the OHT vehicle on the sliding shelf of the target storage unit is completed.

11. An article transfer system comprising:
a traveling rail installed on a ceiling of a facility;
a vehicle moving along the traveling rail and transferring an article; and
a stocker exchanging the article with the vehicle, the stocker including a plurality of storage units storing the article,
wherein the plurality of storage units are disposed in a vertical direction and a horizontal direction in a main frame of the stocker,
each of the plurality of storage units includes a sliding shelf that is withdrawable in both forward and backward directions in a depth direction of the main frame, and
the vehicle directly loads an article onto the withdrawn sliding shelf or directly unloads the article from the withdrawn sliding shelf.

12. The article transfer system of claim 11, further comprising:
a stocker control unit managing a status of an article stored in the plurality of storage units.

13. The article transfer system of claim 12, wherein the stocker control unit receives operation information from the vehicle, determines, based on the operation information, a target storage unit for performing article loading and unloading, among the plurality of storage units, and transmits coordinate information of the target storage unit to the vehicle.

14. The article transfer system of claim 13, wherein the vehicle moves to an upper portion of the target storage unit, and withdraws a sliding shelf of the target storage unit in a forward direction or a backward direction, using a hoist hand.

15. The article transfer system of claim 13, further comprising:
a slide driving unit installed to be adjacent to the main frame, the slide driving unit driving the sliding shelf.

16. The article transfer system of claim 15, wherein the slide driving unit includes:
a traveling mechanism disposed in front of or behind the main frame, the traveling mechanism movable in a horizontal direction of the main frame;
a height adjustment mechanism installed on an upper portion of the traveling mechanism, the height adjustment mechanism adjusting an operation height in a vertical direction of the main frame; and
a shelf operation mechanism withdrawing or inserting the sliding shelf at the operation height.

17. The article transfer system of claim 16, wherein
the stocker control unit transmits the coordinate information of the target storage unit to the slide driving unit, and
the slide driving unit moves the shelf operation mechanism a vicinity of a sliding shelf of the target storage unit, using the traveling mechanism and the height adjustment mechanism.

18. The article transfer system of claim 17, wherein the slide driving unit withdraws the sliding shelf of the target storage unit, using the shelf operation mechanism.

19. The article transfer system of claim 18, wherein the slide driving unit inserts the sliding shelf of the target storage unit after an article loading or unloading operation of the OHT vehicle on the sliding shelf of the target storage unit is completed.

20. An article transfer system comprising:
a traveling rail installed on a ceiling of a facility;
a vehicle moving along the traveling rail and transferring an article; and
a stocker exchanging the article with the vehicle, the stocker including a plurality of storage units storing the article,
wherein the stocker includes:
a plurality of main frames disposed to be spaced apart from each other in a depth direction; and
a plurality of storage units disposed in a vertical direction and a horizontal direction in the plurality of main frames,
each of the plurality of storage units includes a sliding shelf that is withdrawable in both forward and backward directions in the depth direction, and
the vehicle is approachable to one of the plurality of main frames through the traveling rail, and directly loads an article onto the withdrawn sliding shelf or directly unloads the article from the withdrawn sliding shelf.
